(19) United States
(12) Patent Application Publication
(10) Pub. No.: US 2023/0058780 A1
(43) Pub. Date: Feb. 23, 2023

(54) VERIFICATION SYSTEM OR VERIFICATION METHOD FOR DETECTING A CONNECTOR POSITION ASSURANCE (CPA) DEVICE'S CLOSURE RELATIVE TO A HOUSING USING A MACHINE OR ELECTRIC/ELECTRONIC SCAN SYSTEM FOR READING OR DETECTING SURFACE SCAN OF A PREDETERMINED BARCODE OR QR CODE, AND PORTIONS THEREOF

(71) Applicant: J.S.T. CORPORATION, Farmington Hills, MI (US)

(72) Inventor: David DEMARATOS, Wixom, MI (US)

(73) Assignee: J.S.T. CORPORATION, Farmington Hills, MI (US)

(21) Appl. No.: 17/531,641

(22) Filed: Nov. 19, 2021

Related U.S. Application Data
(60) Provisional application No. 63/236,112, filed on Aug. 23, 2021.

(51) Int. Cl. H01R 13/641; G01R 31/67; G06V 30/142

(52) U.S. Cl. CPC H01R 13/641; G01R 31/67; G06V 30/1426

(57) ABSTRACT

A verification system or method for detecting whether a CPA device is in a pre-lock position or in a full-lock position relative to the housing based on a scan system's detection that a portion of a predetermined barcode or QR code on the CPA device and another portion of the predetermined barcode or QR code are separated from each other or joined together to form the predetermined barcode or QR code. The CPA device is fully engaged or in full-lock position or status with the housing when the scan system has recognized or determined that the portion of the predetermined barcode or QR code on the CPA device and the another portion of the predetermined barcode or QR code on the housing within a scan window are joined together to form the complete or full predetermined barcode or QR code.

### CROSS-REFERENCE TO RELATED APPLICATION

This patent application claims priority to U.S. Provisional Patent Application No. 63/236,112 filed Aug. 23, 2021, which is hereby incorporated herein by reference in its entirety.

### BACKGROUND OF THE INVENTION

### 1. Discussions of the Relevant Art

A connector position assurance (CPA) device is known and a well-established component with a well-understood functionality within the industry of connector assemblies and the industries using such devices.

FIGS. 1A, 2A, 3A, 4A, and 5A illustrate conventional connector assemblies, whereby a CPA, although inserted into a housing, remains in an unlocked position or status relative to the housing. FIGS. 1B, 2B, 3B, 4B, and 5B illustrate the conventional connector assemblies, whereby the CPA is pushed away from or pushed towards the housing to place the CPA in a full-locked position or status in the housing.

More particularly, in the conventional connector assembly, illustrated in FIGS. 1A and 1B, the CPA is pushed or moved away from the housing when the CPA and the corresponding housing, either male or female, are viewed at a lateral direction towards corresponding faces thereof to secure the CPA in a full-lock position or status during its engagement with the housing. The conventional connector assemblies, illustrated in FIGS. 2A, 2B, 3A, 3B, 4A, 4B, 5A, and 5B illustrate the CPA to be pushed or moved away from or towards the housing when the CPA and the corresponding housing are viewed at a lateral direction towards corresponding faces thereof to secure the CPA in a full-lock position or status during the engagement with the housing.

In the above-discussed conventional connector assemblies, illustrated in FIGS. 1B, 2B, 3B, 4B, and 5B, the CPA device is captured, in a full-lock position, by the housing (either male or female), and becomes part of the housing. With these conventional connector assemblies, the determination on whether a connector assembly is fully mated falls to the function of the CPA device, and on whether the CPA device is in a full-lockl position relative to the housing of the connector assembly. Thus, there is a need to provide a verification system or verification method for detecting a CPA device's closure, in a full-lock position, using a machine or electric/electronic readable or detectable surface scan system directed to a target size and/or shape on a target surface of the CPA device and/or the corresponding housing.

The following discussions are related to conventional systems for detecting whether elements of conventional electrical connectors have fully mated.

In U.S. Pat. No. 9,583,860, a housing in an electrical connector is made to mate with a connector. The housing includes an indicating feature and a concealing feature, the indicating feature having a visual identifier. The concealing feature conceals at least a portion of the visual identifier in the concealed position, which indicates that the housing and the corresponding connector are not fully mated. On the other hand, when the indicating feature is in the exposed position, this indicates that the housing is fully mated to the corresponding connector.

U.S. Pat. No. 9,583,860 does not, however, teach a verification system or method for detecting that a first visual identifier (e.g., medium number 1) on a first element of the connector and a second visual identifier (e.g., medium number 2) on a second element of the connector are separated to indicate that the first and second elements are not fully mated. Similarly, U.S. Pat. No. 9,583,860 does not teach a verification system or method for detecting that the first visual identifier (e.g., medium number 1) on the first element of the connector and the second visual identifier (e.g., medium number 2) on the second element of the connector are joined together to indicate that the first and second elements are fully mated.

In U.S. Pat. No. 10,651,586, a graphic identifier that is computer-readable and disposed on a display surface of an electrical connector is disclosed. More particularly, a connector position assurance (CPA) device is mounted on a housing and movable relative to the housing between an unlock position and a lock position. In a situation where the CPA device is in the unlock position relative to the housing, the CPA device partially conceals the graphic identifier of the presentation block to prevent the graphic identifier from being read by a reader device. In a situation where the CPA is in a lock position relative to the housing, the graphic identifier of the presentation block is exposed (i.e., the CPA device does not block the graphic identifier).

In other words, in U.S. Pat. No. 10,651,586, the CPA device partially conceals the graphic identifier of the presentation block to prevent the graphic identifier from being read by a reader device; and it is then detected that the CPA device is in the unlock position relative to the housing. On the other hand, also in U.S. Pat. No. 10,651,586, the graphic identifier of the presentation block is exposed because the CPA device does not block the graphic identifier; and it is then detected that the CPA device is in the lock position relative to the housing. U.S. Pat. No. 10,651,586 does not, however, teach a verification system or method for detecting that a first visual identifier (e.g., medium number 1) on a first element of the connector and a second visual identifier (e.g., medium number 2) on a second element of the connector are separated to indicate that the first and second elements are not fully mated. Similarly, U.S. Pat. No. 10,651,586 does not teach a verification system or method for detecting that the first visual identifier (e.g., the medium number 1) on the first element of the connector and the second visual identifier (e.g., the medium number 2) on the second element of the connector are joined together to indicate that the first and second element are fully mated.

In U.S. Pat. No. 8,944,844, an electrical connector having a housing with a first reference number provided thereon, and a mating electrical connector having a latch arm with a second reference number provided thereon. The apparatus in U.S. Pat. No. 8,944,844 is such that the first and second reference numbers are made to align to provide a visual indication that the housing and electrical connector are fully mated.

U.S. Pat. No. 8,944,844 does not, however, teach a verification system or method for detecting that a first visual identifier (e.g., medium number 1) on a first element of the connector and a second visual identifier (e.g., medium number 2) on a second element of the connector are separated to indicate that the first and second elements are not fully mated. Similarly, U.S. Pat. No. 8,944,844 does not teach a verification system and a method for detecting that the first visual identifier (e.g., medium number 1) on the first element of the connector and the second visual identifier (e.g., medium number 2) on the second element of the connector are joined together to indicate that the first and second elements are fully mated.

### 2. Summary of the Invention

It is essential in the connector assembly systems that the locking, preferably in full, of a connector position assurance (CPA) device be certain and assured to ensure that the parts or elements (e.g., a female connector to be connected with a male connector) within a housing are fully-locked, so as to avoid the falling off or dismantling of the female connector, the male connector, or the like from the housing. Generally, the CPA device is captured by either the male housing or the female housing, and the CPA device thereafter becomes part of the male connector assembly or the female connector assembly.

It is thus desired that the verification system or verification method of the full-lock position of the CPA device of this invention be accomplished accurately in a speedy fashion or quick manner.

It is further desired in this invention to provide a visual detectable system or method (generally by a machine, an electric or electronic system) for determining if the CPA device is locked or has been locked, the determination on whether a connector is properly mated to either the male housing or the female housing falling to the function of the CPA device.

This invention is generally directed to a verification system or a verification method for determining whether the CPA device is locked or closed into either a male housing or a female housing using a machine or system that reads or detects a surface scan's at least a predetermined barcode or QR (or Quick Response) code, or portions thereof. It is noted that a QR code or Quick Response code is a type of matrix barcode or two-dimensional barcode. The barcode or QR code may follow international standards or may be of any format that is readable to a machine reader or scanner (such as, custom codes, “one off” codes, or the like).

A predetermined surface of known barcode or QR code is partially formed from a visible surface on the CPA device and is partially formed from a visible feature on a connector housing. This structural arrangement is such that when the CPA device is in a full lock position relative to the housing (i.e., locked or closed), the CPA device forms at least a predetermined complete barcode or QR code, and is distinguishable by a human or an electronic eye (e.g., a machine reader or scanner) from either a partial barcode or QR code that resides on the housing of the CPA device alone; that is, distinguishable from the two partial barcode forms or two partial QR code forms when the CPA device is in the partial-lock position relative to the housing (i.e., open or unlocked).

### BRIEF DESCRIPTION OF THE DRAWINGS

FIG. 1A is an elevational view of a conventional electrical connector assembly having a CPA device in a pre-lock position relative to a corresponding housing.

FIG. 1B is an elevational view of the conventional electrical connector having the CPA device pushed away from the housing resulting in the CPA device becoming fully locked to the corresponding housing.

FIG. 2A is an elevational view of a conventional electrical connector assembly having a CPA device in a pre-lock position relative to a corresponding housing.

FIG. 2B is an elevational view of the conventional electrical connector having the CPA device pushed away from the housing resulting in the CPA device becoming fully locked to the corresponding housing.

FIG. 3A is an elevational view of a conventional electrical connector assembly having a CPA device in a pre-lock position relative to a corresponding housing.

FIG. 3B is an elevational view of the conventional electrical connector having the CPA device pushed towards the housing resulting in the CPA device becoming fully locked to the corresponding housing.

FIG. 4A is an elevational view of a conventional electrical connector assembly having a CPA device in a pre-lock position relative to a corresponding housing.

FIG. 4B is an elevational view of the conventional electrical connector having the CPA device pushed towards the housing resulting in the CPA device becoming fully locked to the corresponding housing.

FIG. 5A is an elevational view of a conventional electrical connector assembly having a CPA device in a pre-lock position relative to a corresponding housing.

FIG. 5B is an elevational view of the conventional electrical connector having the CPA device pushed towards the housing resulting in the CPA device becoming fully locked to the corresponding housing.

FIG. 6A shows top elevational views of a housing and a CPA device of this invention separately showing the housing and the CPA device of this invention, while FIG. 6B further shows the housing and the CPA device of this invention as being operably coupled together.

FIGS. 7A and 7B each shows a side elevational view of the housing having on the upper surface thereof a retention portion for accommodating therein the CPA device and a machine or electric/electronic scan system above the upper surface of the housing for detecting the position or status of the CPA device relative to the housing, FIG. 7A showing the CPA device in a pre-lock position or status relative to the housing, and FIG. 7B showing the CPA device in a full-lock position or status relative to the housing.

FIGS. 8A and 8B each shows a window scan for use by the machine or electric/electronic scan system for detecting a portion of a predetermined barcode on a Medium No. 1 of the CPA device and another portion of the predetermined barcode on Medium No. 2 on the housing within the window scan, FIG. 8A showing the Medium No. 1 of the CPA device not having been joined or connected together with the Medium No. 2 of the housing with the machine or electric/electronic scan system detecting and recognizing the separately and partially formed barcode within the window scan thereby indicating that the CPA device is in a pre-lock position or status relative to the housing, and FIG. 8B showing the Medium No. 1 of the CPA device having been joined or connected together with the Medium No. 2 of the housing with the machine or electric/electronic scan system detecting and recognizing the fully formed barcode within the window scan thereby indicating that the CPA device is in a full-lock position or status relative to the housing.

FIGS. 8C and 8D each shows a window scan for use by the machine or electric/electronic scan system for detecting a portion of a predetermined QR code on a Medium No. 1 of the CPA device and another portion of the predetermined QR code on Medium No. 2 on the housing within the window scan, FIG. 8C showing the Medium No. 1 of the CPA device not having been joined or connected together with the Medium No. 2 of the housing with the machine or electric/electronic scan system detecting and recognizing the separately and partially formed QR code within the window scan thereby indicating that the CPA device is in a pre-lock position or status relative to the housing, and FIG. 8D showing the Medium No. 1 of the CPA device having been joined or connected together with the Medium No. 2 of the housing with the machine or electric/electronic scan system detecting and recognizing the fully formed QR code within the window scan thereby indicating that the CPA device is in a full-lock position or status relative to the housing.

FIGS. 9A and 9B each shows a window scan for use by the machine or electric/electronic scan system for detecting the predetermined barcode of the Medium No. 1 of the CPA device and/or the Medium No. 2 of the housing within the window scan, FIG. 9A showing that the predetermined partial barcode of the Medium No. 1 of the CPA device and/or the Medium No. 2 of the housing has occupied the space within the window scan with the machine or electric/electronic scan system detecting and recognizing only the predetermined partial barcode of the Medium No. 1 of the CPA device and/or the Medium No. 2 of the housing thereby indicating that the CPA device is in a pre-lock position or status relative to the housing, and FIG. 9B showing that the predetermined full barcode of the Medium No. 1 of the CPA device and the Medium No. 2 of the housing has been fully formed together and has occupied the space within the window scan with the machine or electric/electronic scan system detecting and recognizing the fully formed predetermined barcode thereby indicating that the CPA device is in a full-lock position or status relative to the housing.

FIGS. 9C and 9D each shows a window scan for use by the machine or electric/electronic scan system for detecting the predetermined QR code of the Medium No. 1 of the CPA device and/or the Medium No. 2 of the housing within the window scan, FIG. 9C showing that the predetermined partial QR code of the Medium No. 1 of the CPA device and/or the Medium No. 2 of the housing has occupied the space within the window scan with the machine or electric/electronic scan system detecting and recognizing only the predetermined partial QR code of the Medium No. 1 of the CPA device and/or the Medium No. 2 of the housing thereby indicating that the CPA device is in a pre-lock position or status relative to the housing, and FIG. 9D showing that the predetermined full QR code of the Medium No. 1 of the CPA device and the Medium No. 2 of the housing has been fully formed together and has occupied the space within the window scan with the machine or electric/electronic scan system detecting and recognizing the fully formed predetermined QR code thereby indicating that the CPA device is in a full-lock position or status relative to the housing.

FIG. 10 is a flowchart of a verification method of this invention for detecting the CPA device's closure relative to the housing using a machine or electric/electronic scan system for reading or detecting a partial or full surface scan of the Medium No. 1 on the CPA device and the Medium No. 2 on the housing.

FIG. 11 is a flowchart of a verification method of this invention for detecting the CPA device's closure relative to the housing using a machine or electric/electronic scan system for reading or detecting a partial or full surface scan of a portion of a predetermined barcode on the CPA device and another portion of the predetermined barcode on the housing.

FIG. 12 is a flowchart of a verification method of this invention for detecting the CPA device's closure relative to the housing using a machine or electric/electronic scan system for reading or detecting a partial or full surface scan of a portion of a predetermined QR code on the CPA device and another portion of the predetermined QR code on the housing.

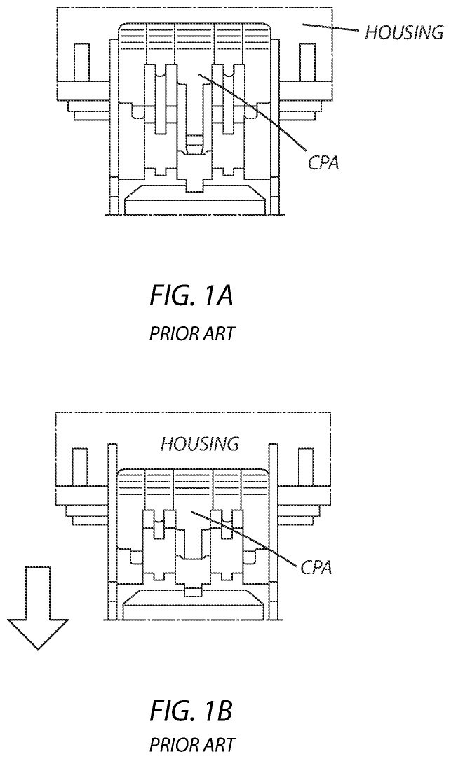

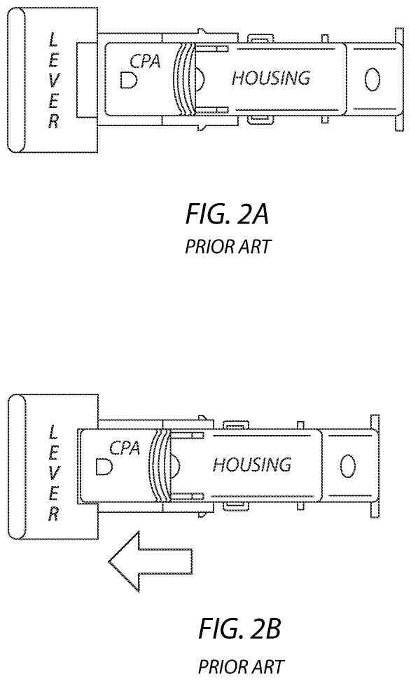

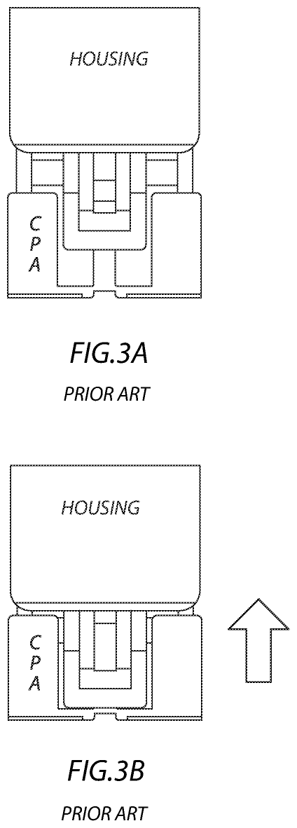

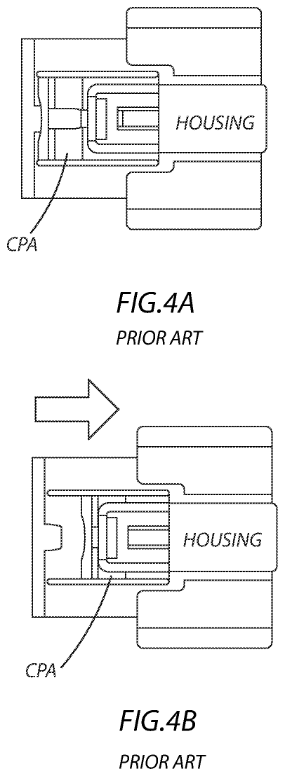

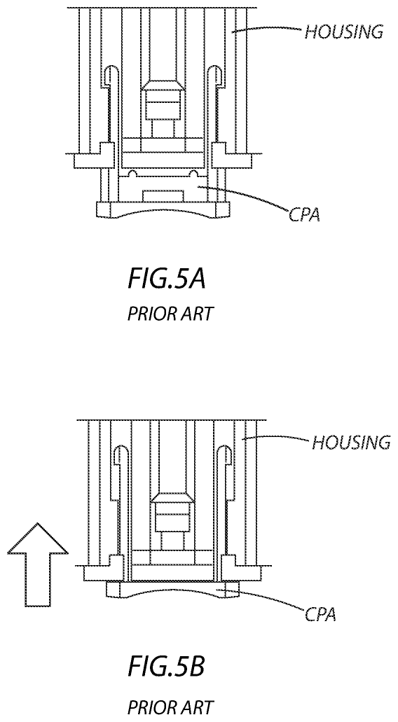

### DETAILED DESCRIPTION OF THE PREFERRED EMBODIMENTS

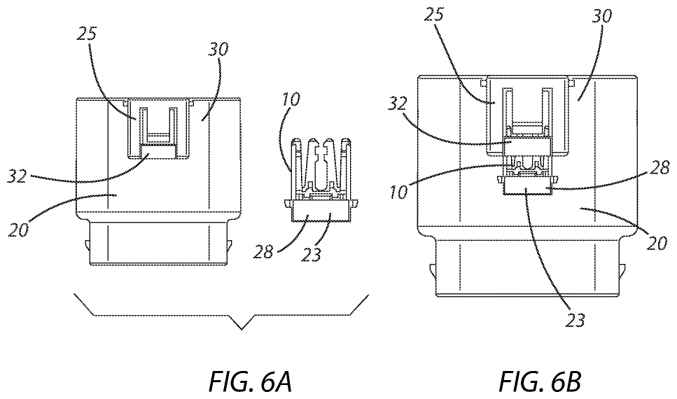

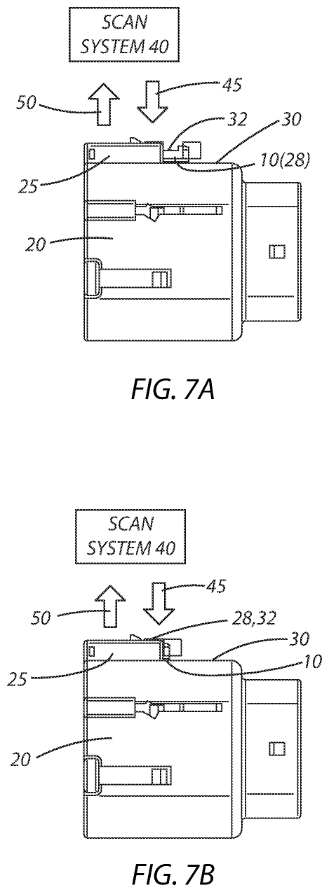

Illustrated in FIG. 6A is, generally, a connector position assurance (CPA) device 10 and a connector assembly housing 20, the CPA device 10 and the housing 20 being shown separately. The housing 20 has an upper surface 30, wherein the upper surface 30 includes a retention portion 25 for accommodating therein the CPA device 10. The CPA device 10 may be a known and a well-established component with a well-understood functionality within the industry of connector assemblies and the industries using such devices. Generally, the CPA device 10, when in a full-lock position relative to the housing 20, ensures that a male terminal and a female terminal (not shown) housed within the housing 20 are fully engaged. Shown on an upper surface 23 of the CPA device 10 is a first visible or visual surface 28 capable of being detected by a machine or electric/electronic scan system 40 (see FIG. 7A). Also shown in FIG. 6A is a second visible or visual surface 32 on the upper surface 30 of the housing 20 similarly capable of being detected by the machine or electric/electronic scan system 40 (see, again, FIG. 7A).

In FIG. 6B, the CPA device 10 is accommodated within the retention portion 25 located in the upper surface 30 of the housing 20. As shown in FIG. 6B, the CPA device 10 is in a pre-lock position and ready to be pushed or moved in the direction towards the housing 20 into a full-lock position. The movement of the first visible or visual surface 28 of the CPA device 10 towards the second visible or visual surface 32 of the housing 20 is monitored or scanned by the machine or electric/electronic scan system 40, as more fully discussed below.

The machine or electric/electronic scan system 40 scans or detects the movement of the first visible or visual surface 28 on the upper surface 23 of the CPA device 10 relative to the second visible or visual surface 32 on the upper surface 30 of the housing 20. The first visible or visual surface 28 of the CPA device 10 may be referred to as a “Medium No. 1,” while the second visible or visual 32 of the housing 20 may be referred to as a “Medium No. 2.” As illustrated in FIG. 7A, the machine or electric/electronic scan system 40 detects that the first visible or visual surface 28 of the CPA device 10 is separated from the second visible or visual surface 32 of the housing 20, as illustrated and discussed earlier with respect to FIG. 6B. The detected separation between the first visible or visual surface 28 of the CPA device 10 and the second visible or visual surface 32 of the housing 20 is an indication that the CPA device 10 is not fully engaged or absorbed within the housing 20; i.e., the CPA device 10 is in a partial lock position or status relative to the housing 20, and not fully engaged with the housing 20. Although the machine or electric/electronic scan system 40 may have an alternative location relative to the upper surface 30 of the housing 20, the machine or electric/electronic scan system 40 may be located such that its scan transmitting signals 45 and scan receiving signals 50 are directed in a direction that is substantially perpendicular to the first visible or visual surface 28 (Medium No. 1) on an upper surface 23 of the CPA device 10 and the second visible or visual surface 32 (Medium No. 2) on the upper surface 30 of the housing 20, or at an angle based on its “angle of attack” in calculating the locations of the first visible or visual surface 28 of the CPA device 10 and/or the second visible or visual surface 32 of the housing 20 that is being scanned. The varied angle may come into play in tight locations where the scan system 40 may have to scan at a specific angle (e.g., 35°-40° or the like) because the scan system 40 may not have an easy access to the first visible or visual surface 28 (Medium No. 1) on an upper surface 23 of the CPA device 10 and/or the second visible or visual surface 32 (Medium No. 2) on the upper surface 30 of the housing 20.

In FIG. 7B, the CPA device 10 has been moved or pushed towards the housing 20; and consequently, the first visible or visual surface 28 (Medium No. 1) of the CPA device 10 has joined or abutted against the second visible or visual surface 32 (Medium No. 2) of the housing 20. The joining or abutting of the first visible or visual surface 28 of the CPA device 10 with the second visible or visual surface 32 of the housing 20 is detected by the machine or electric/electronic scan system 40, which indicates that CPA device 10 is fully engaged with the housing 20 or is in full-lock position or status relative to the housing 20.

Alternatively, in this invention, a predetermined surface of a predetermined or known barcode or QR code can be partially or fully formed on the first visible or visual surface 28 (Medium No. 1) of the CPA device 10, and partially or fully formed on the second visible or visual surface 32 (Medium No. 2) of the housing 20. This structural arrangement or feature is such that when the CPA device 10 is fully engaged or in full-lock position or status relative to the housing 20, the combined first and second visible or visual surfaces 28, 32 (joined Medium No. 1 and Medium No. 2) forms a complete predetermined barcode and/or QR code that is recognizable or distinguishable to a human eye or the electronic eye of the manual or electric/electronic scan system 40. In addition, the human eye or the electronic eye of the manual or electric/electronic scan system 40 should be able to recognize or distinguish that the separation of the first and second visible or visual surfaces 28, 32 (separated Medium No. 1 and Medium No. 2) indicates that the CPA device 10 is not fully engaged with the housing 20 or is in a partial-lock position or status relative to the housing 20.

In this invention, each of the first visible or visual surface 28 (Medium No. 1) and the second visible or visual surface 32 (Medium No. 2) can partially form a predetermined barcode or QR code that will add up to a fully formed predetermined barcode or QR code when placed adjacent to each other, joined together, or abutting each other. For example, either the first visible or visual surface 28 (Medium No. 1) or the second visible or visual surface 32 (Medium No. 2) can make up substantially 25% of the overall recognized predetermined barcode or QR code, and the other surface or medium will by default need to form the remaining substantially 75% of the overall recognized predetermined barcode or QR code. In other words, if the first visible or visual surface 28 (Medium No. 1) or the second visible or visual surface 32 (Medium No. 2) makes up x % of the barcode, the remaining second visible or visual surface 32 (Medium No. 2) or the remaining first visible or visual surface 28 (Medium No. 1) will by default possess the remaining y % of the barcode, where y %=100%−x % of a fully formed barcode. Similarly, if the first visible or visual surface 28 (Medium No. 1) or the second visible or visual surface 32 (Medium No. 2) makes up x % of the QR code, the remaining second visible or visual surface 32 (Medium No. 2) or the remaining first visible or visual surface 28 (Medium No. 1) will by default possess the remaining y % of the QR code, where y %=100%−x % of a fully formed QR code.

Also in this invention, the first visible or visual surface 28 (Medium No. 1) of the CPA device 10 and the second visible or visual surface 32 (Medium No. 2) of the housing 20 will be unable to exhibit a complete overall recognizable or detectable predetermined barcode or QR code when the CPA device 10 is in a partial-lock position or status (also referred to as an “unlocked position” or “open position”) relative to the housing 20. The first visible or visual surface 28 (Medium No. 1) of the CPA device 10 and the second visible or visual surface 32 (Medium No. 2) of the housing 20 are required to form a complete overall recognizable or detectable predetermined barcode or QR code when the CPA device 10 is in a full-lock position or status (also referred to as a “locked position” or “closed position”).

Furthermore, in this invention, the first visible or visual surface 28 (Medium No. 1) of the CPA device 10 and the second visible or visual surface 32 (Medium No. 2) of the housing 20 are distinguishable to a human eye or the machine or electric/electronic scan system 40 with respect to the remaining elements or portions of the CPA device 10 and the housing 20 by contrasting color, UV coating, reflective coating, pad printing, laser etching, engraving, or the like.

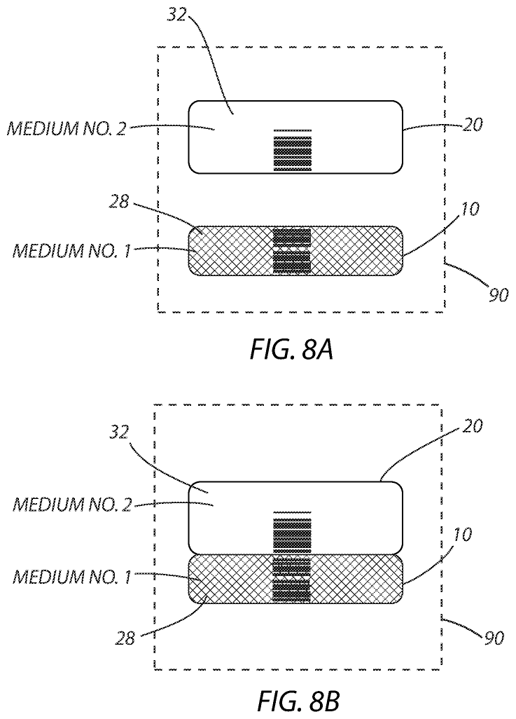

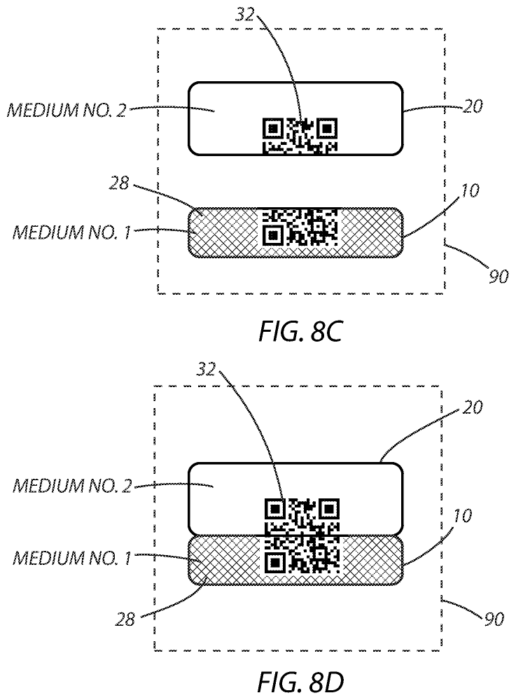

In the embodiment of this invention as illustrated in FIGS. 8A and 8B, each of FIGS. 8A and 8B shows a window scan 90 for use by the machine or electric/electronic scan system 40 for detecting a portion of a predetermined barcode on a Medium No. 1 of the CPA device 10 and another portion of the predetermined barcode on Medium No. 2 on the housing 20 within the window scan 90. In FIG. 8A, it is shown that the Medium No. 1 of the CPA device 10 has not yet been joined or connected together with the Medium No. 2 of the housing 20 with the scan system 40 detecting and recognizing the separately and partially formed barcode within the window scan 90, thereby indicating that the CPA device 10 is in a pre-lock position or status relative to the housing 20. On the other hand, in FIG. 8B, it is shown that the Medium No. 1 of the CPA device 10 has been joined or connected with the Medium No. 2 of the housing 20 with the scan system 40 detecting and recognizing the fully formed barcode within the window scan 90, thereby indicating that the CPA device 10 is in a full-lock position or status relative to the housing 20.

In another embodiment of this invention as illustrated in FIGS. 8C and 8D, each of FIGS. 8C and 8D shows a window scan 90 for use by the machine or electric/electronic scan system 40 for detecting a portion of a predetermined QR code on a Medium No. 1 of the CPA device 10 and another portion of the predetermined QR code on Medium No. 2 on the housing 20 within the window scan 90. In FIG. 8C, it is shown that the Medium No. 1 of the CPA device 10 has not yet been joined or connected together with the Medium No. 2 of the housing 20 with the scan system 40 detecting and recognizing the separately and partially forayed QR code within the window scan 90, thereby indicating that the CPA device 10 is in a pre-lock position or status relative to the housing 20. On the other hand, in FIG. 8D, it is shown that the Medium No. 1 of the CPA device 10 has been joined or connected with the Medium No. 2 of the housing 20 with the scan system 40 detecting and recognizing the fully formed QR code within the window scan 90, thereby indicating that the CPA device 10 is in a full-lock position or status relative to the housing 20.

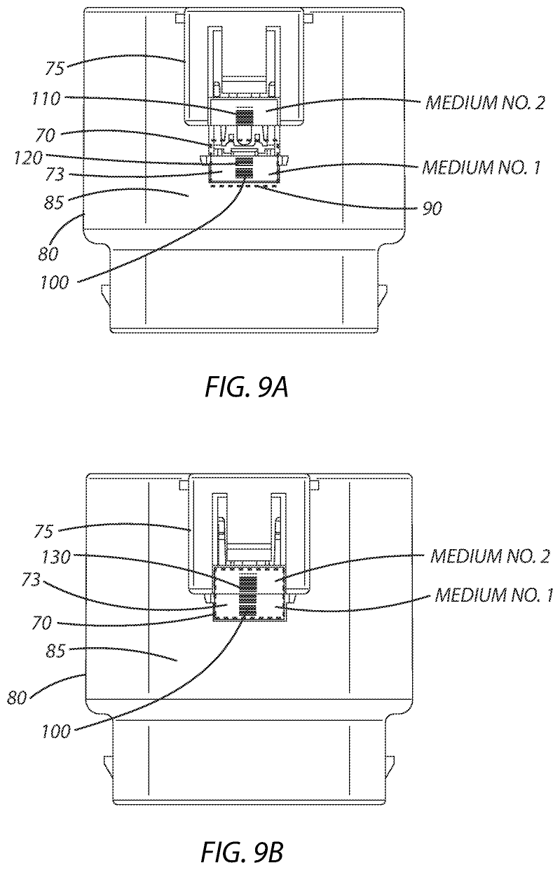

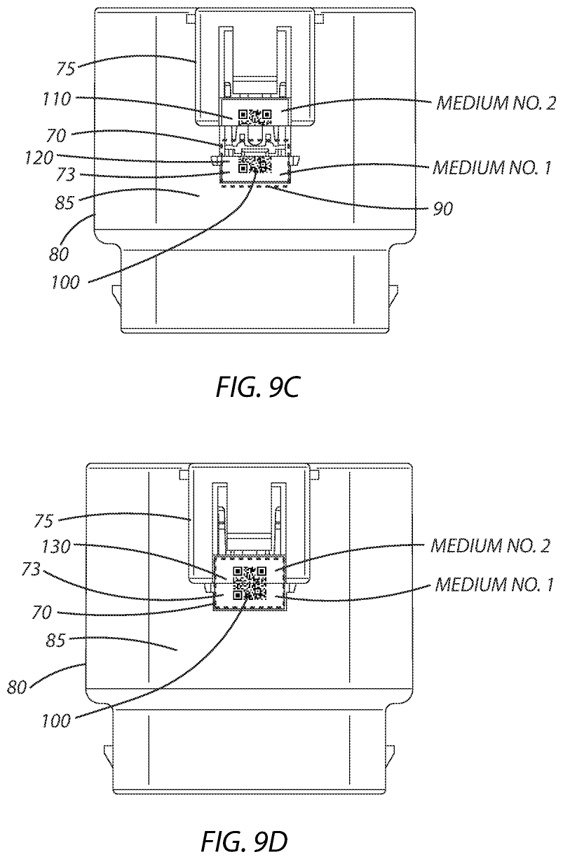

In yet another embodiment of this invention, the machine or electric/electronic scan system 40 determines whether a predetermined percentage of space within a scan window 90 is filled by the Medium No. 1 on an upper surface 73 of the CPA device 70 and/or the Medium No. 2 on an upper surface 85 of the housing 80 for reading or detecting the locking status of the CPA device 70 relative to the housing 80. More particularly, as illustrated in FIGS. 9A and 9B, a retention portion 75 on the upper surface 85 of the housing 80 movably accommodates therein the CPA device 70. As shown in FIG. 9A, the CPA device 70, and therefore the Medium No. 1 thereabove remains at a distance away from the housing 80, and therefore away from the Medium No. 2 thereabove. In this embodiment of this invention, the window scan 90 is focused on the Medium No. 1 of the CPA device 70, as shown in FIG. 9A, and the machine or electric/electronic scan system 40 detects that a predetermined percentage of space 100 within the window scan 90 is not sufficiently or satisfactorily filled by the Medium No. 1 of the CPA device 70 and the Medium No. 2 of the housing 80 with the machine or electric/electronic scan system 40 detecting and recognizing only the predetermined partial barcode on the CPA device 70. Consequently, the machine or electric/electronic scan system 40 detects and records that the CPA device 70 is not fully engaged with the housing 80 or that the CPA device 70 is in a pre-lock position or status relative to the housing 80.

On the other hand, in FIG. 9B, when the CPA device 70 is moved or pushed towards the housing 80, and therefore, the Medium No. 1 of the CPA device 70 is moved or pushed towards the Medium N0. 2 of the housing 80, in this embodiment of this invention, the window scan 90 remains focused on the Medium No. 1 of the CPA device 70, as shown in FIG. 9B, and the machine or electric/electronic scan system consequently detects that a predetermined percentage of space 100 within the window scan 90 is sufficiently or satisfactorily filled by the Medium No. 1 of the CPA device 70 and the Medium No. 2 of the housing 80. Consequently, the machine or electric/electronic scan system 40 detects and recognizes the fully formed predetermined barcode and records that the CPA device 70 is fully engaged with the housing 80 or that the CPA device 70 is in a full-lock position or status relative to the housing 80.

In yet another embodiment of this invention, the machine or electric/electronic scan system 40 determines whether a predetermined percentage of space within a scan window 90 is filled by the Medium No. 1 on an upper surface 73 of the CPA device 70 and/or the Medium No. 2 on an upper surface 85 of the housing 80 for reading or detecting the locking status of the CPA device 70 relative to the housing 80. More particularly, as illustrated in FIGS. 9C and 9D, a retention portion 75 on the upper surface 85 of the housing 80 movably accommodates therein the CPA device 70. As shown in FIG. 9C, the CPA device 70, and therefore the Medium No. 1 thereabove remains at a distance away from the housing 80, and therefore away from the Medium No. 2 thereabove. In this embodiment of this invention, the window scan 90 is focused on the Medium No. 1 of the CPA device 70, as shown in FIG. 9C, and the machine or electric/electronic scan system 40 detects that a predetermined percentage of space 100 within the window scan 90 is not sufficiently or satisfactorily filled by the Medium No. 1 of the CPA device 70 and the Medium No. 2 of the housing 80 with the machine or electric/electronic scan system 40 detecting and recognizing only the predetermined partial QR code on the CPA device 70. Consequently, the machine or electric/electronic scan system 40 detects and records that the CPA device 70 is not fully engaged with the housing 80 or that the CPA device 70 is in a pre-lock position or status relative to the housing 80.

On the other hand, in FIG. 9D, when the CPA device 70 is moved or pushed towards the housing 80, and therefore, the Medium No. 1 of the CPA device 70 is moved or pushed towards the Medium N0. 2 of the housing 80, in this embodiment of this invention, the window scan 90 remains focused on the Medium No. 1 of the CPA device 70, as shown in FIG. 9D, and the machine or electric/electronic scan system consequently detects that a predetermined percentage of space 100 within the window scan 90 is sufficiently or satisfactorily filled by the Medium No. 1 of the CPA device 70 and the Medium No. 2 of the housing 80. Consequently, the machine or electric/electronic scan system 40 detects and recognizes the fully formed predetermined QR code and records that the CPA device 70 is fully engaged with the housing 80 or that the CPA device 70 is in a full-lock position or status relative to the housing 80.

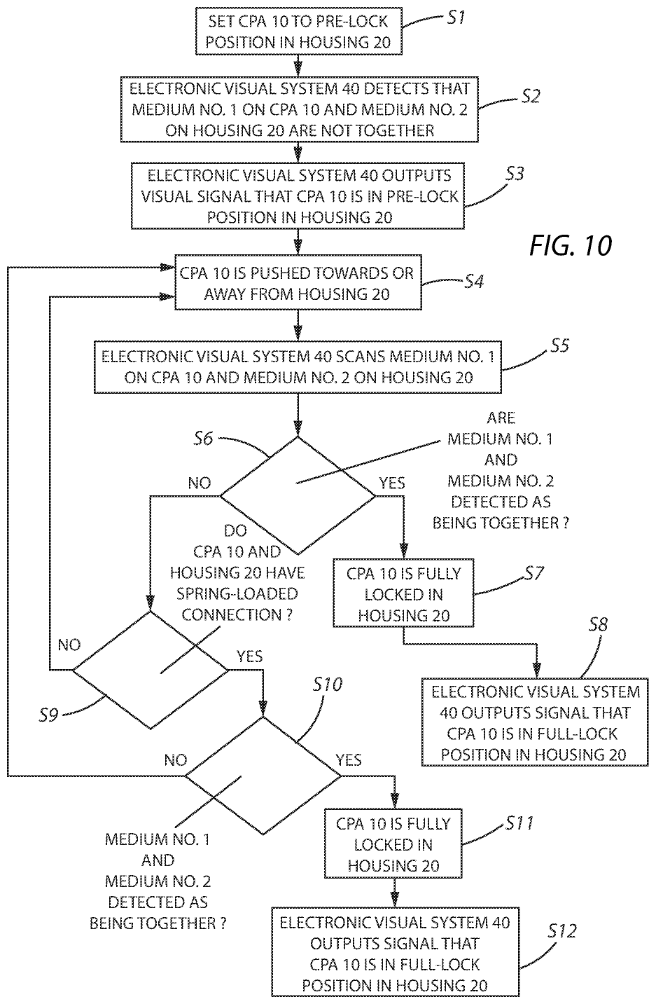

FIG. 10 is a flowchart of a verification method of this invention for detecting the CPA device's closure relative to the housing 20 using a machine or electric/electronic scan system 40, which uses the reference numbers for the initial embodiment described above for this invention, although this flowchart is similarly applicable in the other embodiments described above for this invention.

In the method of this invention, as illustrated in the flowchart of FIG. 10, in Step S1, the CPA device 10 is at a pre-lock position or status relative to the housing 20 (i.e., the CPA device 10 is not fully engaged with the housing 20). The electronic visual system 40 (also referred to above as the “machine or electric/electronic scan system 40”), in Step S2, detects that the Medium No. 1 on the CPA device 10 and the Medium No. 2 on the housing 20 are not yet joined or abutted together. In Step S3, the electronic visual system 40 outputs a visual signal that the CPA device 10 is in a pre-lock position or status relative to the housing 20. Thereafter, in Step S4, the CPA device 10 is moved or pushed towards or away from the housing 20 depending on which connector assembly system described above is applicable.

In this invention, it is preferable that the Medium No. 1 on the CPA device 10 contains thereon a portion of the predetermined barcode or QR code, while the Medium No. 2 on the housing 20 contains thereon another portion of the predetermined barcode or QR code. The portion of the predetermined barcode or QR code on the Medium No. 1 of the CPA device 10 and the another portion of the predetermined barcode or QR code on the Medium No. 2 of the housing 20 form the fully recognizable or detectable predetermined barcode or QR code (scanned and recognized or detected by the electronic visual system 40) when the CPA device 10 is fully engaged with the housing 20 or when the CPA device 10 is in a full-lock position or status with the housing 20.

In Step S5, the electronic visual system 40 scans the Medium No. 1 on the CPA device 20 and the Medium No. 2 on the housing 20; and consequently, the electronic visual system 40 determines in Step S6 whether the Medium No. 1 on the CPA device 10 and the Medium 2 on the housing 20 are jointed together or abutting each other. A decision is then made that if Step S6 is in the affirmative, it is determined in Step S7 that the CPA device 10 is fully engaged or in full-position or status relative to the housing 20; and the electronic visual system 40 outputs a signal that the CPA device 10 is in full-lock position or status relative to the housing 20 in Step S8.

On the other hand, if a decision is made that Step S6 is in the negative, it is further determined in Step S9 whether the CPA device 10 and the housing 20 have a spring-loaded connection. If so, and if it is further detected in Step S10 that the Medium No. 1 on the CPA device 10 and the Medium No. 2 on the housing 20 are joined or abut together, then it is determined in Step S11 that the CPA device 10 is in full engagement with the housing 20 or that the CPA device 10 is in full-lock position or status relative to the housing 20. Thereafter, the electronic visual system 30 outputs a visual signal that the CPA device 10 is in full-lock position or status relative to the housing 20.

If, in Step S9, it is determined that the CPA device 10 and the housing 20 do not have a spring-loaded connection, the method returns to Step S4 whereby the CPA device 10 is moved or pushed towards or away from the housing 20 in Step S4; and the subsequent steps proceed until Step S7 or Step S11 (as discussed above) is reached wherein it is detected that the CPA device 10 is in full-lock position relative to the housing 20, and to Step S8 or Step S12 (as discussed above) wherein the electronic visual system 40 outputs a visual signal that the CPA device 10 is in full-lock position or status relative to the housing 20.

If, in Step S10, it is determined that the Medium No. 1 of the CPA device 10 and Medium No. 2 of the housing 20 are not yet fully pushed together or not yet abutting together, the method returns to Step S4 whereby the CPA device 10 is moved or pushed towards or away from the housing 20 in Step 4; and the subsequent steps proceed until Step S7 or Step S11 (as discussed above) is reached wherein it is detected that the CPA device 10 is in full-lock position relative to the housing 20, and to Step S8 or Step S12 (as discussed above) wherein the electronic visual system 40 outputs a visual signal that the CPA device 10 is in full-lock position or status relative to the housing 20.

In the method of this invention, as illustrated in FIG. 10, because the Medium No. 1 of the CPA device 10 and the Medium No. 2 of the housing 20 respectively contain portions of the predetermined barcode or QR code, the portions of the predetermined barcode or QR code are scanned by the electronic visual system 40 in Step S5. The electronic visual system 40 scans and detects whether the predetermined barcode or QR code has been fully formed and scanned as the fully formed predetermined barcode or QR code in Steps S6 and S10. Upon detection that the predetermined barcode or QR code has fully formed or that the predetermined barcode or QR code has been read and detected by the electronic visual system 40, it is then determined that the CPA device 10 is fully engaged within the housing 20 or that the CPA device 10 is in full-lock position or status with the housing 20.

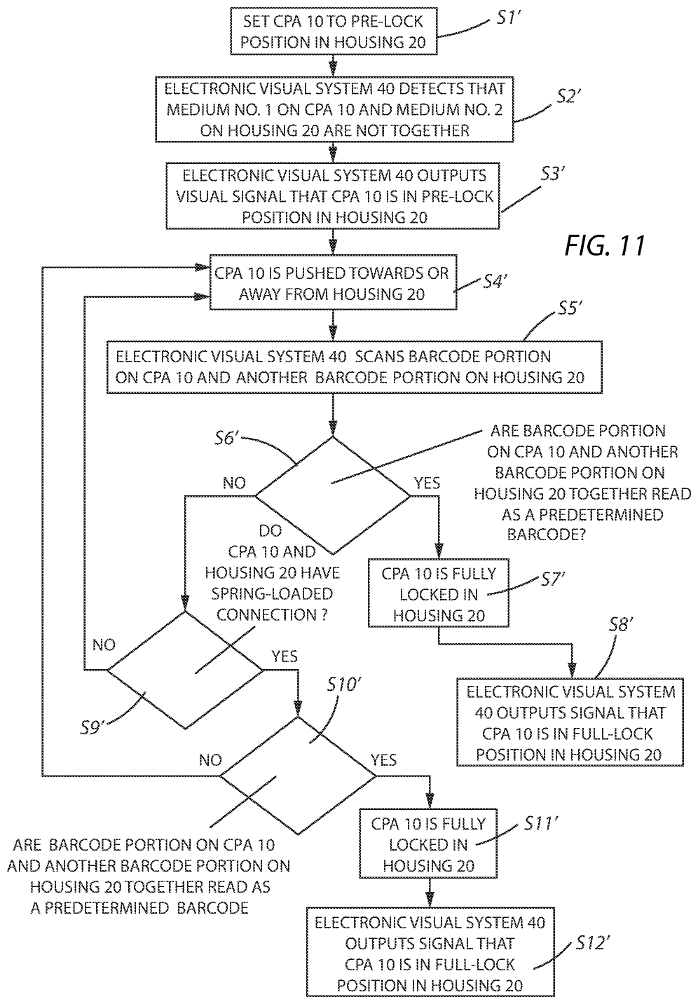

More particularly, in the embodiment of this invention as illustrated in FIG. 11 is a flowchart of a preferable verification method of this invention for detecting the CPA device's 10 closure relative to the housing 20 using the machine or electric/electronic scan system 40 (or in short, the electronic visual system 40) for reading or detecting a partial or full surface scan of a portion of a predetermined barcode on the CPA device 10 and another portion of the predetermined barcode on the housing 20.

In the method of this invention, as illustrated in the flowchart of FIG. 11, in Step S1′, the CPA device 10 is at a pre-lock position or status relative to the housing 20 (i.e., the CPA device 10 is not fully engaged with the housing 20). The electronic visual system 40, in Step S2′, detects that the portion of the predetermined barcode on the CPA device 10 and the another portion of the predetermined barcode on the housing 20 are not yet joined or abutted together. In Step S3′, the electronic visual system 40 outputs a visual signal that the CPA device 10 is in a pre-lock position or status relative to the housing 20. Thereafter, in Step S4′, the CPA device 10 is moved or pushed towards or away from the housing 20 depending on which connector assembly system described above is applicable.

In Step S5′, the electronic visual system 40 scans the portion of the predetermined barcode on the CPA device 20 and the another portion of the predetermined barcode on the housing 20; and consequently, the electronic visual system 40 determines in Step S6′ whether the portion of the predetermined barcode on the CPA device 10 and the another portion of the predetermined barcode on the housing 20 are jointed together or abutting each other. A decision is then made that if Step S6′ is in the affirmative, it is determined in Step S7′ that the CPA device 10 is fully engaged or in full-position or status relative to the housing 20; and the electronic visual system 40 outputs a signal that the CPA device 10 is in full-lock position or status relative to the housing 20 in Step S8′.

On the other hand, if a decision is made that Step S6′ is in the negative, it is further determined in Step S9′ whether the CPA device 10 and the housing 20 have a spring-loaded connection. If so, and if it is further detected in Step S10′ that the portion of the predetermined barcode on the CPA device 10 and the another portion of the predetermined barcode on the housing 20 are joined or abut together, then it is determined in Step S11′ that the CPA device 10 is in full engagement with the housing 20 or that the CPA device 10 is in full-lock position or status relative to the housing 20. Thereafter, the electronic visual system 30 outputs a visual signal that the CPA device 10 is in full-lock position or status relative to the housing 20.

If, in Step S9′, it is determined that the CPA device 10 and the housing 20 do not have a spring-loaded connection, the method returns to Step S4′ whereby the CPA device 10 is moved or pushed towards or away from the housing 20 in Step S4′; and the subsequent steps proceed until Step S7′ or Step S11′ (as discussed above) is reached wherein it is detected that the CPA device 10 is in full-lock position relative to the housing 20, and to Step S8′ or Step S12′ (as discussed above) wherein the electronic visual system 40 outputs a visual signal that the CPA device 10 is in full-lock position or status relative to the housing 20.

If, in Step S10′, it is determined that the portion of the predetermined barcode of the CPA device 10 and the another portion of the predetermined barcode of the housing 20 are not yet fully pushed together or not vet abutting together, the method returns to Step S4′ whereby the CPA device 10 is moved or pushed towards or away from the housing 20 in Step 4′; and the subsequent steps proceed until Step S7′ or Step S11′ (as discussed above) is reached wherein it is detected that the CPA device 10 is in full-lock position relative to the housing 20, and to Step S8′ or Step S12′ (as discussed above) wherein the electronic visual system 40 outputs a visual signal that the CPA device 10 is in full-lock position or status relative to the housing 20.

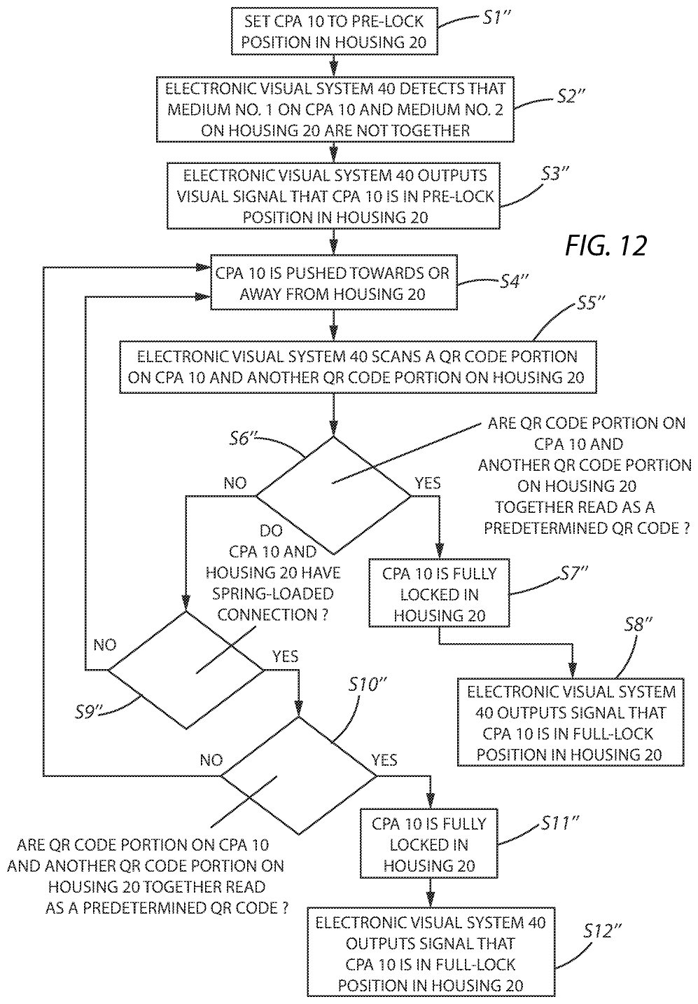

More particularly, in another embodiment of this invention of this invention as illustrated in FIG. 12 is a flowchart of a preferable verification method of this invention for detecting the CPA device's 10 closure relative to the housing 20 using the machine or electric/electronic scan system 40 (or in short, the electronic visual system 40) for reading or detecting a partial or full surface scan of a portion of a predetermined QR code on the CPA device 10 and another portion of the predetermined QR code on the housing 20.

In the method of this invention, as illustrated in the flowchart of FIG. 12, in Step S1″, the CPA device 10 is at a pre-lock position or status relative to the housing 20 (i.e., the CPA device 10 is not fully engaged with the housing 20). The electronic visual system 40, in Step S2″, detects that the portion of the predetermined QR code on the CPA device 10 and the another portion of the predetermined QR code on the housing 20 are not yet joined or abutted together. In Step S3″, the electronic visual system 40 outputs a visual signal that the CPA device 10 is in a pre-lock position or status relative to the housing 20. Thereafter, in Step S4″, the CPA device 10 is moved or pushed towards or away from the housing 20 depending on which connector assembly system described above is applicable.

In Step S5″, the electronic visual system 40 scans the portion of the predetermined QR code on the CPA device 20 and the another portion of the predetermined QR code on the housing 20; and consequently, the electronic visual system 40 determines in Step S6″ whether the portion of the predetermined QR code on the CPA device 10 and the another portion of the predetermined QR code on the housing 20 are jointed together or abutting each other. A decision is then made that if Step S6″ is in the affirmative, it is determined in Step S7″ that the CPA device 10 is fully engaged or in full-position or status relative to the housing 20; and the electronic visual system 40 outputs a signal that the CPA device 10 is in full-lock position or status relative to the housing 20 in Step S8″.

On the other hand, if a decision is made that Step S6″ is in the negative, it is further determined in Step S9″ whether the CPA device 10 and the housing 20 have a spring-loaded connection. If so, and if it is further detected in Step S10″ that the portion of the predetermined QR code on the CPA device 10 and the another portion of the predetermined QR code on the housing 20 are joined or abut together, then it is determined in Step S11″ that the CPA device 10 is in full engagement with the housing 20 or that the CPA device 10 is in full-lock position or status relative to the housing 20. Thereafter, the electronic visual system 30 outputs a visual signal that the CPA device 10 is in full-lock position or status relative to the housing 20.

If, in Step S9″, it is determined that the CPA device 10 and the housing 20 do not have a spring-loaded connection, the method returns to Step S4″ whereby the CPA device 10 is moved or pushed towards or away from the housing 20 in Step S4″; and the subsequent steps proceed until Step S7″ or Step S11″ (as discussed above) is reached wherein it is detected that the CPA device 10 is in full-lock position relative to the housing 20, and to Step S8″ or Step S12″ (as discussed above) wherein the electronic visual system 40 outputs a visual signal that the CPA device 10 is in full-lock position or status relative to the housing 20.

If, in Step S10″, it is determined that the portion of the predetermined QR code of the CPA device 10 and the another portion of the predetermined QR code of the housing 20 are not yet fully pushed together or not yet abutting together, the method returns to Step S4″ whereby the CPA device 10 is moved or pushed towards or away from the housing 20 in Step 4″; and the subsequent steps proceed until Step S7″ or Step S11″ (as discussed above) is reached wherein it is detected that the CPA device 10 is in full-lock position relative to the housing 20, and to Step S8″ or Step S12″ (as discussed above) wherein the electronic visual system 40 outputs a visual signal that the CPA device 10 is in full-lock position or status relative to the housing 20.

The present invention is not limited to the above-described embodiments; and various modifications in design, structural arrangement or the like may be used without departing from the scope or equivalents of the present invention.

I claim:

1. A verification system for detecting a connector position assurance (CPA) device's closure relative to a housing, comprising:
a connector position assurance (CPA) device having a first visible or visual surface with a portion of a predetermined barcode thereon;
a housing having a second visible or visual surface with another portion of the predetermined barcode thereon; and
a scan system that scans said portion of said predetermined barcode on said CPA device and said another portion of said predetermined barcode on said housing, wherein said scan system detects whether said CPA device is in full-lock position relative to said housing depending on whether said scan system detects whether said portion and another portion of said predetermined barcode are separated from each other or joined together.

2. The verification system for detecting said CPA device's closure relative to said housing according to claim 1, wherein said scan system detects that said CPA device is in a pre-lock position relative to said housing upon detection that said portion and another portion of said predetermined barcode are separated from each other.

3. The verification system for detecting said CPA device's closure relative to said housing according to claim 2, wherein said scan system detects that said CPA device is in a full-lock position relative to said housing upon detection that said portion and said another portion of said predetermined barcode are joined together.

4. The verification system for detecting said CPA device's closure relative to said housing according to claim 3, wherein said scan system detects said portion of said predetermined barcode as a first medium, and wherein said scan system detects said another portion of said predetermined barcode as a second medium.

5. The verification system for detecting said CPA device's closure relative to said housing according to claim 1, wherein said scan system is a machine or an electric/electronic scan system.

6. A verification system for detecting a connector position assurance (CPA) device's closure relative to a housing, comprising:
a connector position assurance (CPA) device having a first visible or visual surface with a portion of a predetermined QR code thereon;
a housing having a second visible or visual surface with another portion of the predetermined QR code thereon; and
a scan system that scans said portion of said predetermined QR code on said CPA device and said another portion of said predetermined QR code on said housing, wherein said scan system detects whether said CPA device is in full-lock position relative to said housing depending on whether said scan system detects whether said portion and another portion of said predetermined QR code are separated from each other or joined together.

7. The verification system for detecting said CPA device's closure relative to said housing according to claim 6, wherein said scan system detects that said CPA device is in a pre-lock position relative to said housing upon detection that said portion and another portion of said predetermined QR code are separated from each other.

8. The verification system for detecting said CPA device's closure relative to said housing according to claim 7, wherein said scan system detects that said CPA device is in a full-lock position relative to said housing upon detection that said portion and said another portion of said predetermined QR code are joined together.

9. The verification system for detecting said CPA device's closure relative to said housing according to claim 8, wherein said scan system detects said portion of said predetermined QR code as a first medium, and wherein said scan system detects said another portion of said predetermined QR code as a second medium.

10. The verification system for detecting said CPA device's closure relative to said housing according to claim 6, wherein said scan system is a machine or an electric/electronic scan system.

11. The verification system for detecting said CPA device's closure relative to said housing according to claim 4, wherein said scan system directs a scan window onto at least one of said first medium and said second medium, wherein when said scan system detects that at least one of said first medium and said second medium is a predetermined partial barcode within said scan window, the scan system detects that said CPA device is in a pre-lock position relative to said housing.

12. The verification system for detecting said CPA device's closure relative to said housing according to claim 4, wherein said scan system directs a scan window onto at least one of said first medium and said second medium, wherein when said scan system detects that at least one of said first medium and said second medium is a predetermined full barcode within said scan window, the scan system detects that said CPA device is in a full-lock position relative to said housing.

13. The verification system for detecting said CPA device's closure relative to said housing according to claim 4, wherein when said scan system detects that a percentage of at least one of said first medium and said second medium is zero within said scan window, the scan system detects that said CPA device is in a pre-lock position relative to said housing.

14. The verification system for detecting said CPA device's closure relative to said housing according to claim 9, wherein said scan system directs a scan window onto at least one of said first medium and said second medium, wherein when said scan system detects that at least one of said first medium and said second medium is a predetermined partial QR code within said scan window, the scan system detects that said CPA device is in a pre-lock position relative to said housing.

15. The verification system for detecting said CPA device's closure relative to said housing according to claim 9, wherein said scan system directs a scan window onto at least one of said first medium and said second medium, wherein when said scan system detects that at least one of said first medium and said second medium is a predetermined full QR code within said scan window, the scan system detects that said CPA device is in a full-lock position relative to said housing.

16. A verification method for detecting a connector position assurance (CPA) device's closure relative to a housing, comprising the steps of:
providing a connector position assurance (CPA) device having a partial portion of a predetermined barcode or QR code on a first visible or visual surface thereof;
providing a housing having another portion of said predetermined barcode or QR code on a second visible or visual surface thereof; and
scanning by a scan system at least one of said partial portion of said predetermined barcode or QR code on said first visible or visual surface of said CPA device and said another partial portion of said predetermined barcode or QR code on said second visible or visual surface of said housing, wherein said scanning step is comprised of a step of detecting whether said CPA device is in a pre-lock position or in a full-lock position relative to said housing based on whether said scan system detects whether said partial portion of said predetermined barcode or QR code on said first visible or visual surface of said CPA device and said another partial portion of said predetermined barcode or QR code on said second visible or visual surface of said housing are separated from each other or joined together.

17. The verification method for detecting said connector position assurance (CPA) device's closure relative to said housing according to claim 16, wherein said scanning step is comprised of a step of detecting that said CPA device is in a pre-lock position relative to said housing upon detection that said partial portion of said predetermined barcode on said first visible or visual surface of said CPA device and said another partial portion of said predetermined barcode on said second visible or visual surface of said housing are separated from each other.

18. The verification method for detecting said connector position assurance (CPA) device's closure relative to said housing according to claim 16, wherein said scanning step is comprised of a step of detecting that said CPA device is in a full-lock position relative to said housing upon detection that said partial portion of said predetermined barcode on said first visible or visual surface of said CPA device and said another partial portion of said predetermined barcode on said second visible or visual surface of said housing are joined together.

19. The verification method for detecting said connector position assurance (CPA) device's closure relative to said housing according to claim 16, wherein said scanning step is comprised of a step of detecting that said CPA device is in a pre-lock position relative to said housing upon detection that said partial portion of said predetermined QR code on said first visible or visual surface of said CPA device and said another partial portion of said predetermined QR code on said second visible or visual surface of said housing are separated from each other.

20. The verification method for detecting said connector position assurance (CPA) device's closure relative to said housing according to claim 16, wherein said scanning step is comprised of a step of detecting that said CPA device is in a full-lock position relative to said housing upon detection that said partial portion of said predetermined QR code on said first visible or visual surface of said CPA device and said another partial portion of said predetermined QR code on said second visible or visual surface of said housing are joined together.
